(19) United States
(12) Patent Application Publication
(10) Pub. No.: US 2015/0016046 A1
(43) Pub. Date: Jan. 15, 2015

(54) INA CABLED MEMORY APPLIANCE

(71) Applicant: Samsung Electronics Co., Ltd., Suwon-si (KR)

(72) Inventor: Ian P. SHAEFFER, Los Gatos, CA (US)

(73) Assignee: Samsung Electronics Co., Ltd., Suwon-si (KR)

(21) Appl. No.: 14/091,316

(22) Filed: Nov. 26, 2013

Related U.S. Application Data
(60) Provisional application No. 61/844,835, filed on Jul. 10, 2013.

(51) Int. Cl. G06F 1/16; H05K 13/04; H01R 43/00

(52) U.S. Cl. CPC G06F 1/16; H01R 43/00; H05K 13/0486
USPC 361/679.32; 29/825

(57) ABSTRACT

According to one general aspect, an apparatus may include an expansion memory device, a connection printed circuit board, and a connection cable. The expansion memory device may include a plurality of memory chips. The connection printed circuit board may be configured to be physically coupled with a memory socket. The connection cable may be configured to electrically couple the connection printed circuit board with the expansion memory device and transmit electrical signals therebetween.

### CROSS-REFERENCE TO RELATED APPLICATION

This application claims priority under 35 U.S.C. §119 to Provisional Patent Application Ser. No. 61/844,835, entitled “A CABLED MEMORY APPLIANCE” filed on Jul. 10, 2013. The subject matter of this earlier filed application is hereby incorporated by reference.

### TECHNICAL FIELD

This description relates to a memory device, and more specifically to low-latency remote memory extension or expansion device.

### BACKGROUND

Main or system memory in a computing device often includes dynamic random access memory (DRAM) arranged in modules. These modules often include various memory integrated circuits or chips (for storing information or data) that are soldered or otherwise connected to a printed circuit board. Frequently, these memory chips are arranged in a dual in-line memory module (DIMM) or single in-line memory module (SIMM) configuration.

The computing device frequently includes a motherboard or other central component. Generally, a motherboard is the main printed circuit board (PCB) of a computer and other expandable systems. It often holds many of the electronic components of the system, such as the central processing unit (CPU) and memory, and provides connectors for other peripherals. In various embodiments, the motherboard (or similar board) may include memory sockets or slots that are configured to house various memory modules. In such a system, it is possible to remove or add memory modules (from/to the memory sockets) in order to adjust the amount of system memory within the computing device. As such, memory modules are often standardized within a range of options that include both capacity (e.g., 1 Gigabyte (Gb), 4 GB, 16 Gb, etc.), communications protocol (e.g., PC3-17000, PC2-6400, 333 MHz data & strobe with 166 MHz clock for address & control, 1866 MHz data & strobe with 933 MHz clock for address & control, etc.), form factor (e.g., low profile DIMMS, heights of 1.2, 1.5, 1.7 inches, 244-pin, 200-pin, 172-pin, MiniDIMM, SO-DIMM, etc.), electrical characteristics (e.g., 5 Volt (V), 3V, etc.), and capabilities (e.g., error correction, serial presence detect (SPD), etc.). Often the amount of memory available to the system is limited by the number of memory modules (or memory sockets for the memory modules) the motherboard can support.

Many computer applications (e.g. datacenter applications) require large amounts of DRAM memory. Unfortunately, it is becoming increasingly difficult to add more memory to server systems. Increasing the bus speeds used to communicate with the memory modules, among other factors, often causes the number of possible memory modules in the system to be reduced due to signaling challenges. In such a scenario the data rate to the memory may increase but that may cause the amount of memory in the system to decrease. Meanwhile, the applications using servers are requiring an increasing amount of memory that is outpacing the system's ability to provide it. For example, memory databases may need terabytes (TB) of memory to run efficiently.

### SUMMARY

According to one general aspect, an apparatus may include an expansion memory device, a connection printed circuit board, and a connection cable. The expansion memory device may include a plurality of memory chips. The connection printed circuit board may be configured to be physically coupled with a memory socket. The connection cable may be configured to electrically couple the connection printed circuit board with the expansion memory device and transmit electrical signals therebetween.

According to another general aspect, a system may include a processor, a memory socket, an expansion memory device, a connection printed circuit board, and a connection cable. The processor may be configured to execute instructions and access data stored within a memory chip. The memory socket may be configured to electrically couple the processor with a memory chip. The expansion memory device may include a plurality of memory chips. The connection printed circuit board may be configured to be physically coupled with a memory socket. The connection cable may be configured to electrically couple the printed circuit board with the expansion memory device and transmit electrical signals therebetween.

According to another general aspect, a method may include fixedly attaching an expansion memory device within a component bay of a computing system. The expansion memory device may include a plurality of memory chips, each memory chip configured to store data. The method may include coupling the expansion memory device with a connection cable, wherein the connection cable is configured to transport signals between the expansion memory device and a memory connector plug. The method may also include coupling the memory connector plug with a memory socket, wherein the memory socket is configured to receive a memory access request from a memory management unit.

The details of one or more implementations are set forth in the accompanying drawings and the description below. Other features will be apparent from the description and drawings, and from the claims.

A system and/or method for storing information, substantially as shown in and/or described in connection with at least one of the figures, as set forth more completely in the claims.

### BRIEF DESCRIPTION OF THE DRAWINGS

FIG. 1a is a block diagram of an example embodiment of a system in accordance with the disclosed subject matter.

FIG. 1b is a block diagram of an example embodiment of a system in accordance with the disclosed subject matter.

FIG. 2 is a block diagram of an example embodiment of a system in accordance with the disclosed subject matter.

FIG. 3 is a block diagram of an example embodiment of a device in accordance with the disclosed subject matter.

FIG. 4 is a block diagram of an example embodiment of a system in accordance with the disclosed subject matter.

FIG. 5 is a flow chart of an example embodiment of a technique in accordance with the disclosed subject matter.

FIG. 6 is a block diagram of an example embodiment of a system in accordance with the disclosed subject matter.

Like reference symbols in the various drawings indicate like elements.

### DETAILED DESCRIPTION

Various example embodiments will be described more fully hereinafter with reference to the accompanying drawings, in which some example embodiments are shown. The present disclosed subject matter may, however, be embodied in many different forms and should not be construed as limited to the example embodiments set forth herein. Rather, these example embodiments are provided so that this disclosure will be thorough and complete, and will fully convey the scope of the present disclosed subject matter to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosed subject matter.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present disclosed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present disclosed subject matter.

Unless otherwise defined, all terms (including technical and scientific terms) used herein have the same meaning as commonly understood by one of ordinary skill in the art to which this disclosed subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

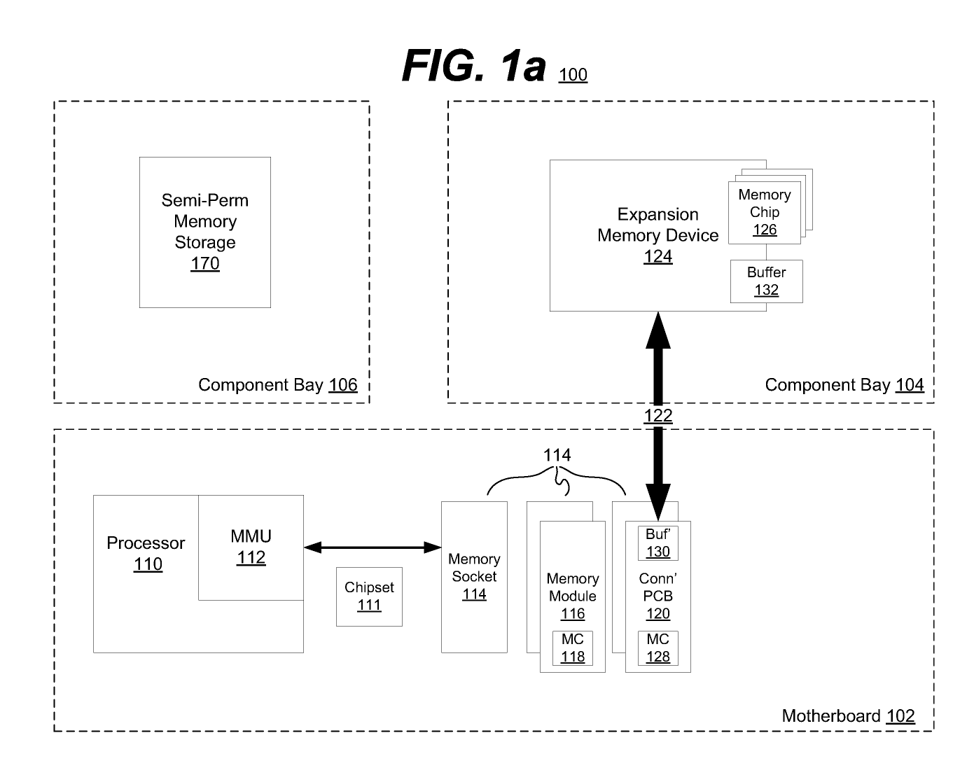

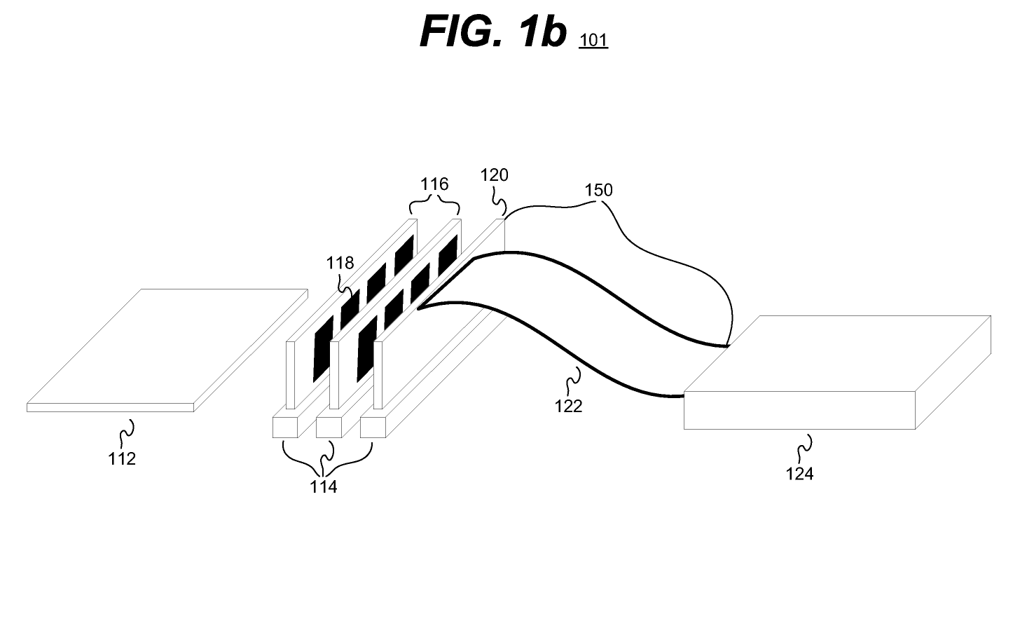

FIG. 1a is a block diagram of an example embodiment of a system 100 in accordance with the disclosed subject matter. In various embodiments, the system 100 may include a computing device, such as a laptop, desktop, workstation, personal digital assistant, smartphone, tablet, and other appropriate computers, etc.

In various embodiments, the system 100 may be used by a user (not shown). In various embodiments, the system 100 may include a processor 110 configured to execute one or more machine executable instructions or pieces of software, firmware, or a combination thereof. The system 100 may include, in some embodiments, a memory configured to store one or more pieces of data, either temporarily, permanently, semi-permanently, or a combination thereof. Further, the memory may include volatile memory, non-volatile memory or a combination thereof. In various embodiments, the system 100 may include a storage medium (e.g., semi-permanent memory storage 170) configured to store data in a semi-permanent or substantially permanent form.

In the illustrated embodiment, the system 100 may include a motherboard 102. In such an embodiment, the motherboard 102 may be configured to electrically connect a number of components of the computing device 100 (e.g., the processor 110, the memory, a network interface (not shown), etc.).

In various embodiments, the system 100 may also include a number of component bays (e.g., bays 104 & 106). In such an embodiment, each component bay may be configured to house or provide a way to fixedly attach a modular hardware component (e.g., a hard drive, a flash drive, an expansion memory device, etc.). In the specific example of a hard drive bay, the component bay may be configured to accept or mount 3.5″ or 2.5″ hard drive form factors. In another embodiment, the component bay may be configured to accommodate or house other form factors (e.g., a solid-state drive (SSD), optical drive, tape-back-up drive, etc.).

In the illustrated embodiment, the system 100 may include two component bays 104 and 106. In one embodiment, a first component bay 106 may house or include a semi-permanent memory storage 170. In various embodiments, this semi-permanent memory storage 170 may include a hard drive or other non-volatile memory system. In such an embodiment, the semi-permanent memory storage 170 may be configured to store data for relatively long-term storage and retrieval. In one embodiment, the semi-permanent memory storage 170 may be configured to communicate this data with the processor 110 and other components of the system 100 (e.g., memory chips 118, 126, and/or 128, etc.).

Returning to the motherboard 102, in various embodiments, the motherboard 102 may electrically connect the processor 110 with one or more memory chips (e.g., memory chips 118, etc.). In such an embodiment, the memory chips may include a plurality of DRAM memory elements each configured to temporarily store data. In various embodiments, these memory chips may include volatile storage. In another embodiment, one or more of these memory chips may include non-volatile storage. In some embodiments, the various memory chips (e.g., memory chips 118, 126, and/or 128) may include a combination of volatile and non-volatile memory storage. It is understood that the above are merely a few illustrative examples to which the disclosed subject matter is not limited.

In some embodiments, the processor 110 may communicate with the memory chips via a memory management unit (MMU) 112. In various embodiments, the MMU 112 may be configured to regulate and manage memory accesses by the processor 110 to the memory chips. In one embodiment, the MMU 112 may be included with or integrated as part of the processor 110. In another embodiment, the system 100 may include a chipset 111 that includes the MMU 112. In such an embodiment, the chipset 111 may include a plurality of integrated circuits or chips that are configured to manage the data flow between the processor, memory and peripherals (not shown). It is understood that the above are merely a few illustrative examples to which the disclosed subject matter is not limited.

In one embodiment, the motherboard 102 may include a fixed number of memory sockets 114, as described above. In such an embodiment, the memory sockets 114 may be configured to electrically connect a memory chip 118 with the MMU 112, and may further be configured to physically couple a memory module 116 with the motherboard 102. As described above, in such an embodiment, the memory socket 114 may include a certain form factor that corresponds to a given standard or form factor of the memory module 116 such that memory modules 116 of other form factors are not physically able to be coupled with the memory socket 114.

As described above, in various embodiments, the system 100 may include a memory module 116. In such an embodiment, the memory module 116 may include one or more memory chips 118. Each memory chip 118 may be configured to store various pieces of data, as described above. In some embodiments, the memory module 116 may include a plurality of these memory chips 118 arranged in an in-line fashion. In some embodiments, the memory module 116 may include a printed circuit board (PCB) having two sides and these memory chips 118 may be arranged or fastened to one or both sides of the PCB. It is understood that the above are merely a few illustrative examples to which the disclosed subject matter is not limited.

In various embodiments, the various memory chips 118 may include a plurality of locations where each piece of data may be stored. Each of these locations may be associated with at least one memory address. In such an embodiment, when the MMU 112 requests a memory access (e.g., a memory read, a memory write, etc.) the request may include a memory address that indicates which memory chip 118 or at least which memory module 116 or memory socket 114 includes the destination or desired memory location associated with the data of the memory access.

However, as described above, in an embodiment that only includes memory modules 116 the number of possible memory locations or addresses are limited by the number of memory sockets 114 available. Further, there are both electrical and mechanical considerations to adding a large number of memory sockets 114 (and therefore more memory chips 118) to the motherboard 102. Therefore, computing devices almost always include far less memory than the MMU 112 or the processor 110 could theoretically support (e.g., 16 exabytes for 64-bit processors, 5 petabytes for some implementations of 64-bit processors, etc.).

In the illustrated embodiment, the system 100 may include an expansion memory device 124. In various embodiments, the expansion memory device 124 may include one or more memory chips 126. As described above, memory chips 126 may be configured to store data. In various embodiments, the memory chips 118 may utilize a one or memory technologies (e.g., DRAM, Spin-transfer torque (STT), flash, Phase-change memory (PCM), Resistive RAM, Static RAM, etc.). In some embodiments, the expansion memory device 124 may include more memory chips 126 than the memory module 116. In another embodiment, the expansion memory device 124 may include memory chips 126 with a greater storage capacity than the memory module 116. In such an embodiment, the expansion memory device 124 may provide a significant increase in the memory capacity of the system 100, as compared to the memory module 116.

In the illustrated embodiment, the expansion memory device 124 may be housed or fixedly attached within the component bay 104. In another embodiment, the expansion memory device 124 may be placed, attached, or mounted within another part of the system 100. For example, if the motherboard 102 and component bay 106 (and more generally the system 100) are housed within an enclosure (not shown), it may occur that a part of the enclosure is empty or may include a void. In some embodiments, the expansion memory device 124 may be placed, attached, or mounted so as to, at least partially, fill the void. It is understood that the above is merely one illustrative example to which the disclosed subject matter is not limited.

In various embodiments, the system 100 may include a connection PCB or memory connector plug 120. In such an embodiment, the connection PCB 120 may be configured to be physically coupled with a memory socket 114. In such an embodiment, the connection PCB 120 may have a form factor substantially similar to the memory module 116 such that it may plug-into or be mechanically coupled with the memory socket 114 in a similar fashion. For example, in various embodiments, the connection PCB 120 may have a similar form factor to a DIMM or SIMM. It is understood that the above are merely a few illustrative examples to which the disclosed subject matter is not limited.

In one embodiment, the connection PCB 120 and the expansion memory device 124 may be electrically connected via a connection cable 122. In such an embodiment, signals received by the connection PCB 120 may be transmitted to the expansion memory device 124, and vice versa.

In various embodiments, the connection cable 122 may include a plurality of wires, with each wire being dedicated to an electrical pathway. In another embodiment, the connection cable 122 may include one electrical pathway for each of the electrical pathways provided by the memory socket 114, such that signals received by the memory socket 114 may be carried by the connection cable 122 without alteration. In another embodiment, the connection cable 122 may include a different number of electrical pathways than the memory socket 114. For example, the memory socket 114 may be configured for parallel operation and the connection cable 122 may be configured for serial operation. In yet another embodiment, the connection cable 122 may include optical pathways. It is understood that the above are merely a few illustrative examples to which the disclosed subject matter is not limited.

In such an embodiment, the MMU 112 may transmit a memory access request (e.g., a read, a write, etc.) to the connection PCB 120. This memory access request may then be transmitted, via the connection cable 122, to the expansion memory device 124. The memory access may be performed by the appropriate memory chip 126 and the results (if any) may be transmitted back to the MMU 112 (via the connection cable 122 and the connection PCB 120).

In one embodiment, the addition to the system 100 of the expansion memory device 124, the connection cable 122, and the connection PCB 120 may allow a significant increase in the memory capacity of the system 100 without the need to alter the motherboard 102 or the need to increase the number of memory sockets 114. Further, in various embodiments, the ability to mount the expansion memory device 124 within a pre-existing component bay 104 (e.g., one designed to house a hard drive, etc.) may allow the increase of system memory without the need to redesign the enclosure used by the system 100. It is understood that the above are merely a few illustrative examples to which the disclosed subject matter is not limited.

In various embodiments, the MMU 112 may communicate with the connection PCB 120 using the same protocol that is used to communicate with the memory module 116. In such an embodiment, the MMU 112 may be unaware that the memory chips 126 are stored within the expansion memory device 124 as opposed to a memory module 116. Conversely, in a less preferred embodiment, the MMU 112 may communicate with the connection PCB 120 using a different protocol than the one used to communicate with the memory module 116.

In one embodiment, the connection PCB 120 may simply transmit the signals or messages received from the MMU 112 (e.g., a read command, etc.) to the expansion memory device 124 without alteration. However, in various embodiments, the connection PCB 120 may include one or more buffer or repeater circuits 130. In such an embodiment, the buffer circuits 130 may be configured to provide electrical power to the signals being transmitted across the connection cable 122. In such an embodiment, this may reduce the loading on the motherboard memory bus (not explicitly shown). In another embodiment, the buffer chip or circuit 130 may be configured to increase the speed of the signals across the connection cable 122, reduce the capacitive load on the signals, increases the signal integrity, etc. It is understood that the above are merely a few illustrative examples to which the disclosed subject matter is not limited. Likewise, in various embodiments, the expansion memory device 124 may include one or more buffer circuits or chips 132 for similar reasons.

As described above, in various embodiments, the buffer circuits or chips 130 may be configured to convert the memory bus signaling to something more appropriate for transmission over a connection cable 122 of sufficient length to get to the free space (e.g., a previously unused component bay 104, etc.) that includes the expansion memory device 124. In some embodiments, this may include altering the messages or signals from a first to a second protocol or encoding. In another embodiment, this may include converting the form of the signals (e.g., from electrical to light, etc.) It is understood that the above are merely a few illustrative examples to which the disclosed subject matter is not limited.

In some embodiments, a single buffer circuit 130 may be employed. In another embodiment, multiple buffer circuits 130 may be included. In one embodiment, this may be to minimize the bus stub length relative to the connection PCB 120 and provides the highest or relatively higher signal integrity on the motherboard 102. It is understood that the above is merely one illustrative example to which the disclosed subject matter is not limited.

In various embodiments, the buffer circuits 132 of the expansion memory device 124 may be configured to convert the received memory signals from the second protocol or encoding back to the first protocol or encoding. In another embodiment, the buffer circuits 132 may be configured to provide electrical decoupling from the connection cable 122. In yet another embodiment, the buffer circuits 132 of the expansion memory device 124 may be configured to operate only on signals transmitted by the of the expansion memory device 124 and not signals received via the connection cable 122. It is understood that the above are merely a few illustrative examples to which the disclosed subject matter is not limited.

In various embodiments, the buffer circuits 130 & 132 may include additional logic or features beyond acting as a transceiver. In one embodiment, the transmitted signals may simply be serialized from the memory bus. In another embodiment, the received signals may be transformed in some other way (e.g. packetized, encoded, etc.), as described above. In one embodiment, minimal changes may be made to the received signals, only doing as much as was necessary to be transmitted over the connection cable 122. In another embodiment, the connection PCB 120, and more specifically circuits that are represented in the illustrated embodiment as buffers 130, may be configured to perform local memory management before transmitting the memory access requests from the MMU 112 to the expansion memory device 124. In various embodiments, these memory management operations may include re-ordering a series of memory access commands or operations, caching data locale within the connection PCB 120 (e.g., via memory circuits 128) and deciding when to fulfill the memory access request from the cache, when to synchronize the cache with the expansion memory device, etc. It is understood that the above are merely a few illustrative examples to which the disclosed subject matter is not limited. In such an embodiment, the buffer circuit 130 may also include one or more of a memory controller, a translation look aside buffer, an address translation buffer, a reorder buffer, a memory management unit, etc.

In various embodiments, the connection PCB 120 may include one or more memory chips 128. As described above, in various embodiments, these memory chips 128 may serve as a cache to temporarily store data that will ultimately be stored within the expansion memory device 124. In another embodiment, the memory chips 128 may be configured to act similarly to or store data similarly to the memory chips 118 of the memory module 116. In such an embodiment, the connection PCB 120 may determine, based upon the memory address associated with the memory access operation, whether or not to transmit the memory access request from the MMU 112 to either the memory chips 126 of the expansion memory device 124 or the memory chips 128 that are locally included by the connection PCB 120. In such an embodiment, the connection PCB 120 may be configured to act as a memory module 116 if the connection cable 122 is not attached.

In various embodiments, the connection PCB 120 may be configured to, when attached, query the expansion memory device 124 for the amount of storage capacity provided by the expansion memory device 124. In such an embodiment, this capacity may be reported to the MMU 112, in order for the MMU 112 to understand the amount of total system memory provided by the memory modules 116 and the expansion memory device(s) 124. In another embodiment, the storage capacity of the expansion memory device 124 may be predefined or stored within the connection PCB 120 such that a query operation is not performed. In yet another embodiment, the connection PCB 120 may be configured to add the amount of storage provided by the expansion memory device 124 to any amount of storage provided by the memory chips 128 before informing the MMU 112 of the amount of memory associated with the connection PCB 120. It is understood that the above are merely a few illustrative examples to which the disclosed subject matter is not limited.

In one specific embodiment, the system 100 may include two processors 110, each with two component bays 106 designed for a hard drive form factor (such that four hard drives 170 may be included in total). In such an embodiment, one of the component bays 106 for each processor 110 may be replaced with an expansion memory device 124 cabled from one of the respective processor's 110 memory slots or sockets 114 to the component bay 104 that houses the expansion memory device 124. In various embodiments, the expansion memory devices 124 may be configured to make use of the existing power, reset, and any other infrastructure already available in the component bay 104. It is understood that the above is merely one illustrative example to which the disclosed subject matter is not limited.

In another example embodiment, a system 100 may include two processors 110 and 12 component bays 104 and 106, each component bay may be configured to house a hard drive form factor. Further the system 100 may include 16 memory sockets 114. In such an embodiment, most (e.g., ten, etc.) of the hard drives 170 may be replaced by expansion memory devices 124. This would allow for a massive amount of main memory in the system 100 compared to traditional computing systems. It is understood that the above is merely one illustrative example to which the disclosed subject matter is not limited.

FIG. 1b is a block diagram of an example embodiment of a system 101 in accordance with the disclosed subject matter. In the illustrated embodiment, the system 101 may include a simplified version or diagram of the system 100 of FIG. 1a. In such an embodiment, like reference symbols in the various drawings indicate like elements.

In various embodiments, the connection cable 122 may include a cable or bundle of electrical wires or Fibre optics. In another embodiment, the connection cable 122 may include flexible plastic such as flexible PCB, polyimide, polyether ether ketone (PEEK) and/or transparent conductive polyester film, etc. It is understood that the above are merely a few illustrative examples to which the disclosed subject matter is not limited.

Conversely, in various embodiments, the connection PCB 120 may include a rigid PCB or other electrical structure. In some embodiments, the connection cable 122 and the connection PCB 120 may be included by or integrated into a single component, the integrated connection cable 150. In one such embodiment, connection cable portion 122 may be made from flexible electronics and the connection PCB portion 120 may be made from rigid or semi-rigid electronics. In such an embodiment, the connection cable 122 or integrated connection cable 150 may include its own connector that plugs into the memory socket 114. It is understood that the above is merely one illustrative example to which the disclosed subject matter is not limited.

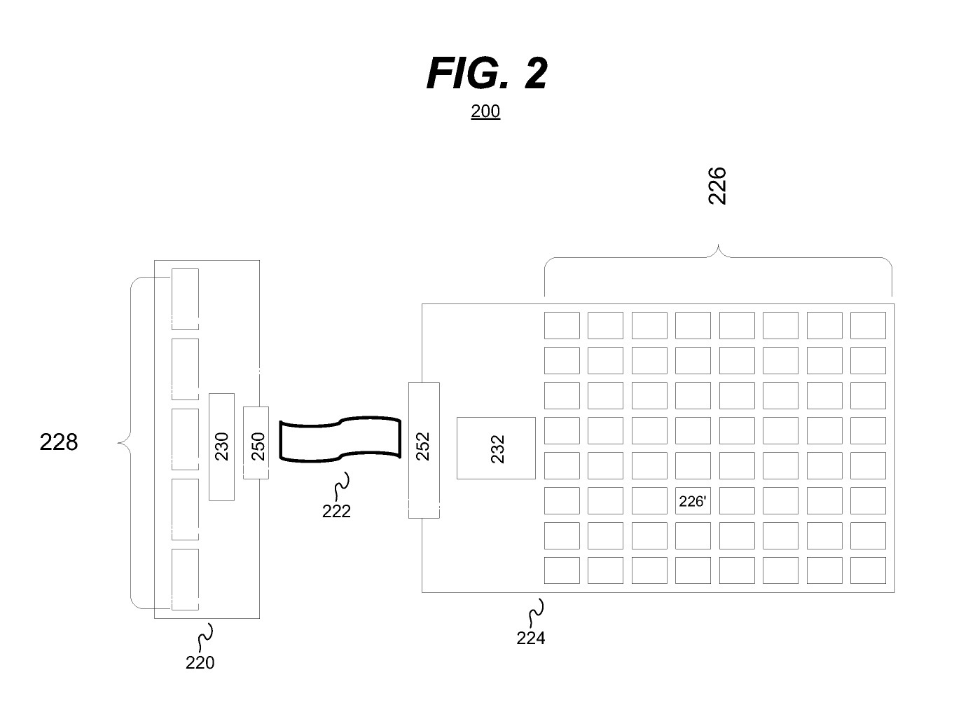

FIG. 2 is a block diagram of an example embodiment of a system 200 in accordance with the disclosed subject matter. In the illustrated embodiment, the system 200 may include an expansion memory device 224, a connection PCB or memory connector plug 220, and a connection cable 222, similarly to those described above.

As described above, in various embodiments, the expansion memory device 224 may include a plurality of memory chips 226. In the illustrated embodiment, it can be seen that the expansion memory device 224 may include a far greater number of memory chips 226 than the memory modules described in FIGS. 1a and 1b.

The following are rough potential capacities of the expansion memory device 224. In some embodiments, a standard DIMM memory module may have a surface area of approximately 5.25″ by 1.2″ or 6.3 in². In one embodiment, an expansion memory device 224 that has a form factor adapted to fit within a 3.5″ hard drive component bay may have a surface area of 4″ by 5.75″ or 23 in². This may provide a single PCB 3.5″ form factor expansion memory device 224 with a capacity of about 4 standard DIMM memory modules. In another embodiment, an expansion memory device 224 that has a form factor adapted to fit within a 2.5″ hard drive component bay may have a surface area of 2.75″ by 3.945″ or 10.85 in². This may provide a single PCB 2.5″ form factor expansion memory device 224 with a capacity of about 1.7 standard DIMM memory modules. In yet another embodiment, other expansion memory devices 224 may be shaped to conform to other form factors similar to other devices (e.g., SSDs, Peripheral Component Interconnect (PCI) cards, etc.). In such an embodiment, these expansion memory devices 224 may provide more or even less space for memory chips 226 than the standard DIMM memory module. And, it is understood that as the storage capacity (e.g., 1 GB, 4 GB, etc.) of memory chips 226 increases or varies, the storage capacity of the expansion memory device 224 may vary. It is also understood that the above are merely a few illustrative examples to which the disclosed subject matter is not limited.

In various embodiments, the expansion memory devices 224 may include a buffer circuit 232. In such an embodiment, the buffer circuit 232 may be configured to receive signals from the connection PCB 220, via the connection cable 222. The buffer circuit 232 may then forward those signals or new signals derived from the received signals to the respective memory chips 228. As described above, in some embodiments, the buffer circuit or circuits 232 may be configured to make use of the same protocol as that received by the connection PCB 220. In another embodiment, the buffer circuit 232 may be configured to use a second protocol and may reformat or transcode the signals as needed. In yet another embodiment, the connection PCB 220 may convert signals from a first protocol to a second protocol for transmission via the connection cable 222, and the buffer circuit 232 may convert the signals from the second protocol back to the first protocol or, in some embodiments, a third protocol. It is understood that the above are merely a few illustrative examples to which the disclosed subject matter is not limited.

As described above, In various embodiments, the buffer circuit 232 may be configured to receive, via the connection cable 222, data that is associated with a memory address, determine, based at least in part upon the memory address, a destination memory chip 226′ of the plurality of memory chips that 226 the data is associated with, and transmit the data to the destination memory chip 226′. In some embodiments, the buffer chip 232 may include a memory management unit configured to route and otherwise manage memory access operations (e.g., caching, synchronization, adjusting an order of memory operations, etc.) on the expansion memory device 224.

In various embodiments, the expansion memory device 224 may include a cable connector 252. In such an embodiment, the cable connector 252 may be configured to couple the connection cable 222 with the expansion memory device 224. In various embodiments, the cable connector 252 may be integrated in whole or part with the buffer circuit 232. In some embodiments, the expansion memory device 224 may include a plurality of buffer circuits 232 and/or cable connectors 252.

In some embodiments, the connection PCB or memory connector plug 220 may include a cable connector 250 configured to couple the connection PCB 220 with the connection cable 222. As described above, in various embodiments, the connection PCB 220 and the connection cable 222 may be integrated.

In one embodiment, the connection PCB 220 may include one or more buffer circuits 230. In such an embodiment, the buffer circuit 230 may be configured to perform similarly to that of the buffer circuit 232 of the expansion memory device 224. As described above, in various embodiments, the buffer circuit 230 may re-format or transcode signals travelling across the connection cable 222. As described above, in some embodiments, the buffer circuit 230 may include or be configured to perform memory management functions (e.g., operation reordering, caching, synchronizing, etc.). In another embodiment, the buffer circuit 230 may merely boost or provide additional electrical power to aid or adjust the electrical characteristics of the memory signals, as described above.

In one embodiment, the connection PCB 220 may include one or more memory chips 228. As described above, in some embodiments, the memory chips 228 may be configured to cache data which may then be more permanently stored within the memory chips 226 of the expansion memory device 224. As described above, in another embodiment, the memory chips 228 may function in addition to the memory chips 226, such that each memory chip 228 or 226 has a separately accessible memory address and may store separate pieces of data. It is understood that the above are merely a few illustrative examples to which the disclosed subject matter is not limited.

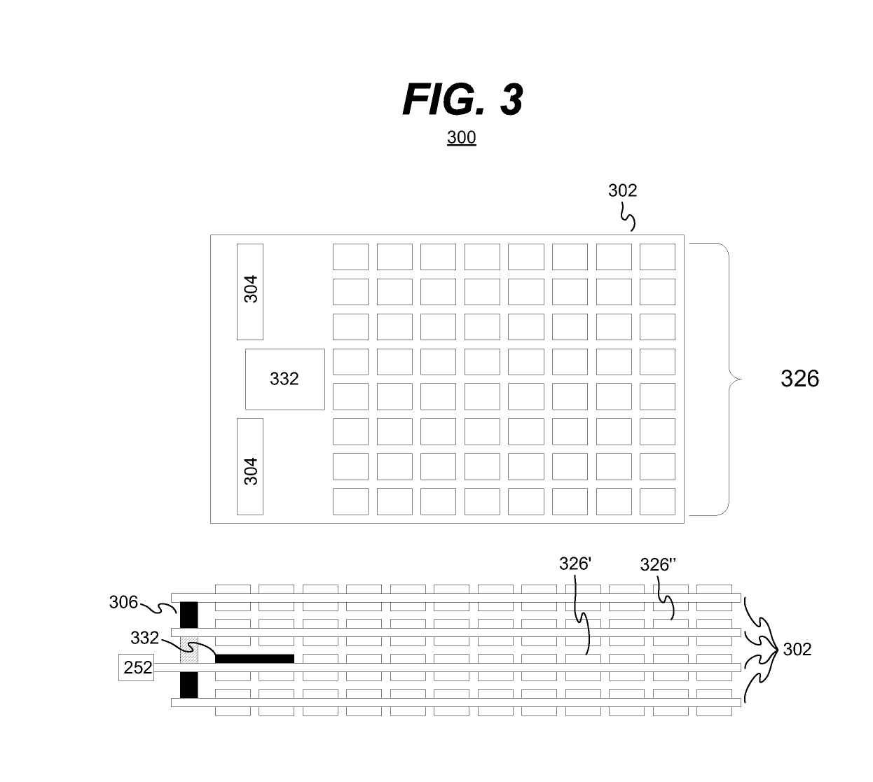

FIG. 3 is a block diagram of an example embodiment of a device 300 in accordance with the disclosed subject matter. In various embodiments, the device may include an expansion memory device that in turn includes a plurality of printed circuit boards or memory cards 302.

In the illustrated embodiment, the expansion memory device 300 may be not a single printed circuit board (PCB) with memory chips 326, such that of FIG. 2. Instead the expansion memory device 300 may include a plurality of PCBs 302 each with respective memory chips 326. In various embodiments, the other substrates may be employed instead of PCBs and the PCBs 302 may more generally be referred to as memory cards 302. In the illustrated embodiment, the memory cards 302 may be horizontally stacked such that the expansion memory device 300 has a three dimensional characteristic (as opposed to the relatively two-dimensional DIMM memory module or expansion memory device 224 of FIG. 2). It is understood that the above is merely one illustrative example to which the disclosed subject matter is not limited.

In various embodiments, one or more of the PCBs 302 may include a buffer circuit 332. As described above, in various embodiments, the buffer circuit 332 may include various memory management functions. In the illustrated embodiment, the buffer circuit 332 may be configured to determine (e.g., based upon a memory address, etc.) which memory chip is being accessed (e.g., via a read or a write operation, etc.) and then access the destination or target memory chip accordingly. It is understood that the above is merely one illustrative example to which the disclosed subject matter is not limited.

For example, in one embodiment, the buffer circuit 332 may determine that memory chip 326′ is being accessed. In the illustrated embodiment, the memory chip 326′ is included by the same PCB 302 as the buffer circuit 332. Therefore, the forwarding of the memory access may be relatively simple.

In another example embodiment, the buffer circuit 332 may determine that memory chip 326″ is being accessed. In the illustrated embodiment, the memory chip 326″ is included a different PCB 302 than the buffer circuit 332. In such an embodiment, the expansion memory device 300 may include one or more PCB connectors 304 configured to electrically couple the PCBs 302 together. In various embodiments, the expansion memory device 300 may include one or more intra-device connection cables or posts 306. In various embodiments, the intra-device connection cables 306 may be flexible. In another embodiment, intra-device connection cables 306 may be rigid or semi-rigid such that one end of the intra-device connection cables 306 is configured to snap or plug into a respective PCB connector 304. It is understood that the above are merely a few illustrative examples to which the disclosed subject matter is not limited.

In such an example embodiment, once the buffer circuit 332 has determined that the destination or target memory chip 326″ is included by another PCB 302, the buffer circuit 332 may transmit the memory access, via the respective intra-device connection cables 306 and the a respective PCB connector 304. In some embodiments, the PCB connector 304 may be configured to determine if the memory access is for a memory chip on the same PCB 302 as the PCB connector 304. If so, the PCB connector 304 may terminate the signals. If not, the PCB connector 304 may retransmit or forward the memory access to another PCB 302. In yet another embodiment, the PCB connector 304 may be included as part of a shared memory bus between the PCBs 302. In various embodiments, a number of possible transmission protocols for communicating between the PCBs 302 may be employed.

In some embodiments, the PCB connector 304 may include circuits similar (at least in part) to the buffer circuit 332 or the buffer circuit 232 of FIG. 2. In another embodiment, the PCB connector 304 may merely include a socket or other physical connector. It is understood that the above are merely a few illustrative examples to which the disclosed subject matter is not limited.

Returning to the rough capacity calculations from above, in one embodiment, an expansion memory device 300 that has a form factor adapted to fit within a 3.5″ hard drive component bay may have a height of 1″ and may include, for example, 4 PCBs 302. This may provide a multiple PCB 3.5″ form factor expansion memory device 300 with a capacity of about 16 standard DIMM memory modules. In another embodiment, an expansion memory device 300 that has a form factor adapted to fit within a 2.5″ hard drive component bay may have a height of between 0.275″ and 0.59″ and may include 2 PCBs 302. This may provide a multiple PCB 2.5″ form factor expansion memory device 300 with a capacity of about 3.5 standard DIMM memory modules. In yet another embodiment, the expansion memory device 300 may have a similar form factor to another component (e.g., SSD, PCI card, etc.). In another embodiment, the PCBs or memory cards 302 may be of different sizes or different memory capacities. In such an embodiment, the expansion memory device 300 may be configured to fit within a non-rectangular or right-angled parallelepiped space, bay, or enclosure. In various embodiments, PCBs 302 may be modular, hot-swappable, and/or user adjustable. It is understood that the above are merely a few illustrative examples to which the disclosed subject matter is not limited.

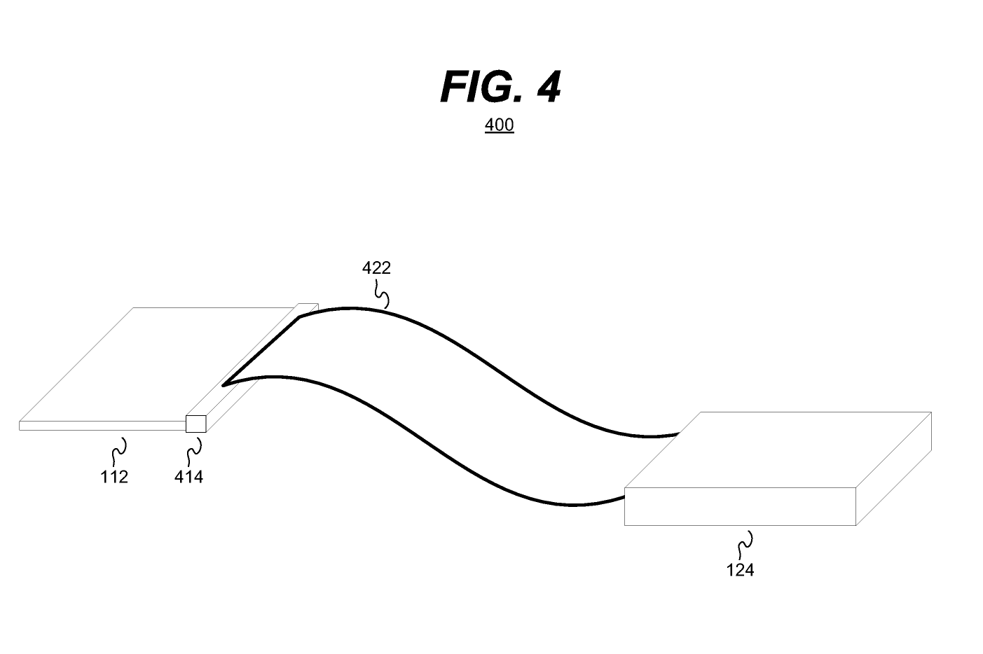

FIG. 4 is a block diagram of an example embodiment of a system 400 in accordance with the disclosed subject matter. In the illustrated embodiment, the system 400 may include a MMU 112 and an expansion memory device 124, as described above. However, in such an embodiment, the system 400 may not include the connection PCB or memory connector plug (e.g., of FIG. 1a, etc.).

In the illustrated embodiment, the MMU 112 may include an integrated cable connector 414 configured to accept or be coupled with the connection cable 422. In such an embodiment, the expansion memory device 124 may not be coupled with a traditional memory socket (such as in FIG. 1a), but may instead be configured to coupled directly or more directly with the MMU 112, via the cable connector 414.

In one embodiment, the cable connector 414 may include a socket or plug that is configured to directly receive the connection cable 422. In another embodiment, the cable connector 414 may include a plurality of pins of the MMU 112 that are configured to be coupled with the expansion memory device 124 via the connection cable 422. In such an embodiment, the connection cable 422 may be soldered or otherwise fixedly attached to the cable connector 414. It is understood that the above are merely a few illustrative examples to which the disclosed subject matter is not limited.

In another embodiment, the cable connector 414 not be integrated directly with the MMU 112 and may simply be part of a motherboard or similar component. In such an embodiment, the cable connector 414 may not include the memory module form factor. It is understood that the above is merely one illustrative example to which the disclosed subject matter is not limited.

As described above, in various embodiments, the connection cable 422 may include a connector. In such an embodiment, the connection cable 422 may be configured to plug directly into the cable connector 414 without the need to a connection PCB. It is understood that the above is merely one illustrative example to which the disclosed subject matter is not limited.

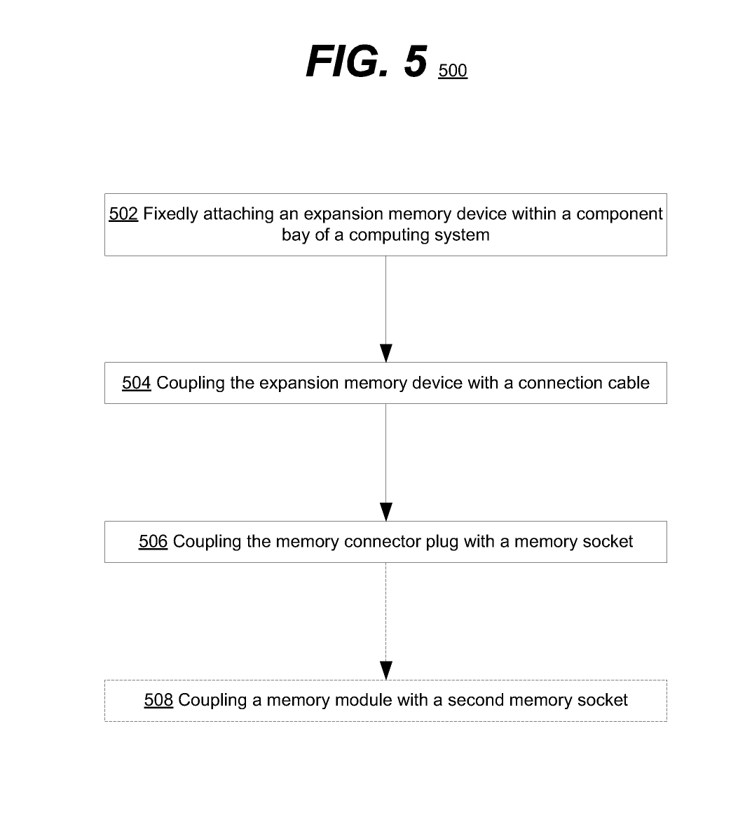

FIG. 5 is a flow chart of an example embodiment of a technique in accordance with the disclosed subject matter. In various embodiments, the technique 500 may be used or produced by the systems such as those of FIG. 1a, 1b, 3, 4, or 6. Furthermore, portions of technique 500 may be used or produced by the systems such as that of FIG. 1a, 1b, 3, 4, or 6. Although, it is understood that the above are merely a few illustrative examples to which the disclosed subject matter is not limited. It is understood that the disclosed subject matter is not limited to the ordering of or number of actions illustrated by technique 500.

Block 502 illustrates that, in one embodiment, an expansion memory device may be fixedly attached within a component bay of a computing system, as described above. In various embodiments, the expansion memory device may include a plurality of memory chips, each memory chip configured to store data, as described above. In some embodiments, fixedly attaching the expansion memory device may include removing a hard drive from the component bay, as described above. In various embodiments, the expansion memory device may include a plurality of modular memory cards, as described above. In such an embodiment, each memory card may include a plurality of memory chips, as described above. In various embodiments, one or more of the action(s) illustrated by this Block may be performed by the apparatuses or systems of FIG. 1a, 1b, 2, 3, or 4; the expansion memory device 124 of FIG. 1a or 1b, as described above.

Block 504 illustrates that, in one embodiment, the expansion memory device may be coupled with a connection cable, as described above. In some embodiments, the connection cable may be configured to transport signals between the expansion memory device and a memory connector plug, as described above. In various embodiments, one or more of the action(s) illustrated by this Block may be performed by the apparatuses or systems of FIG. 1a, 1b, 2, 3, or 4; the connection cable of FIG. 1a, 1b, 2, 3, or 4, as described above.

Block 506 illustrates that, in one embodiment, the memory connector plug may be coupled with a memory socket, as described above. In various embodiments, the memory socket may be configured to receive a memory access request from a memory management unit, as described above. In various embodiments, one or more of the action(s) illustrated by this Block may be performed by the apparatuses or systems of FIG. 1a, 1b, 2, 3, or 4; the memory socket of FIG. 1a, 1b, 2, 3, or 4, as described above.

Block 508 illustrates that, in one embodiment, a memory module may be coupled with a second memory socket, as described above. In such an embodiment, the memory module may include a second plurality of memory chips, as described above. In such an embodiment, the memory management unit may be configured to access, via a first protocol, either a memory chip of the expansion memory device or a memory chip of the memory module, as described above. In various embodiments, one or more of the action(s) illustrated by this Block may be performed by the apparatuses or systems of FIG. 1a, 1b, 2, 3, or 4; the memory module and memory management unit of FIG. 1a, 1b, 2, 3, or 4, as described above.

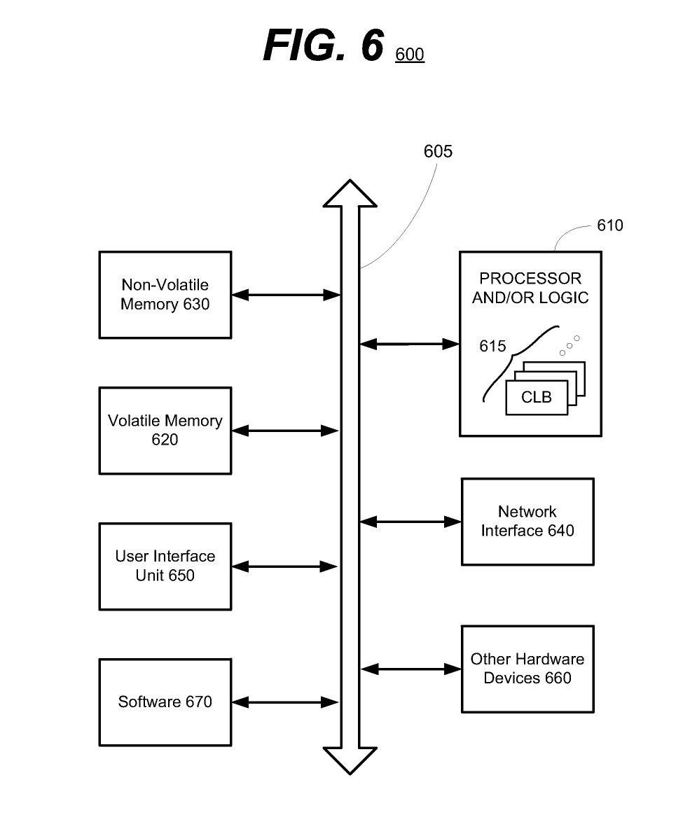

FIG. 6 is a schematic block diagram of an information processing system 600 which may include semiconductor devices formed according to principles of the disclosed subject matter.

Referring to FIG. 6, an information processing system 600 may include one or more of devices constructed according to the principles of the disclosed subject matter. In another embodiment, the information processing system 600 may employ or execute one or more techniques according to the principles of the disclosed subject matter.

In various embodiments, the information processing system 600 may include a computing device, such as, for example, a laptop, desktop, workstation, server, blade server, personal digital assistant, smartphone, tablet, and other appropriate computers, etc. or a virtual machine or virtual computing device thereof. In various embodiments, the information processing system 600 may be used by a user (not shown).

The information processing system 600 according to the disclosed subject matter may further include a central processing unit (CPU), processor or logic 610. In some embodiments, the processor 610 may include one or more functional unit blocks (FUBs) or combinational logic blocks (CLBs) 615. In such an embodiment, a combinational logic block may include various Boolean logic operations (e.g., NAND, NOR, NOT, XOR, etc.), stabilizing logic devices (e.g., flip-flops, latches, etc.), other logic devices, or a combination thereof. These combinational logic operations may be configured in simple or complex fashion to process input signals to achieve a desired result. It is understood that while a few illustrative examples of synchronous combinational logic operations are described, the disclosed subject matter is not so limited and may include asynchronous operations, or a mixture thereof. In one embodiment, the combinational logic operations may comprise a plurality of complementary metal oxide semiconductors (CMOS) transistors. In various embodiments, these CMOS transistors may be arranged into gates that perform the logical operations; although it is understood that other technologies may be used and are within the scope of the disclosed subject matter.

The information processing system 600 according to the disclosed subject matter may further include a volatile memory 620 (e.g., a Random Access Memory (RAM), etc.). The information processing system 600 according to the disclosed subject matter may further include a non-volatile memory 630 (e.g., a hard drive, an optical memory, a NAND or Flash memory, etc.). In some embodiments, either the volatile memory 620, the non-volatile memory 630, or a combination or portions thereof may be referred to as a “storage medium”. In various embodiments, the memories 620 and/or 630 may be configured to store data in a semi-permanent or substantially permanent form.

In various embodiments, the information processing system 600 may include one or more network interfaces 640 configured to allow the information processing system 600 to be part of and communicate via a communications network. Examples of a Wi-Fi protocol may include, but are not limited to: Institute of Electrical and Electronics Engineers (IEEE) 802.11g, IEEE 802.11n, etc. Examples of a cellular protocol may include, but are not limited to: IEEE 802.16m (a.k.a. Wireless-MAN (Metropolitan Area Network) Advanced), Long Term Evolution (LTE) Advanced), Enhanced Data rates for GSM (Global System for Mobile Communications) Evolution (EDGE), Evolved High-Speed Packet Access (HSPA+), etc. Examples of a wired protocol may include, but are not limited to: IEEE 802.3 (a.k.a. Ethernet), Fibre Channel, Power Line communication (e.g., HomePlug, IEEE 1901, etc.), etc. It is understood that the above are merely a few illustrative examples to which the disclosed subject matter is not limited.

The information processing system 600 according to the disclosed subject matter may further include a user interface unit 650 (e.g., a display adapter, a haptic interface, a human interface device, etc.). In various embodiments, this user interface unit 650 may be configured to either receive input from a user and/or provide output to a user. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input.

In various embodiments, the information processing system 600 may include one or more other hardware components or devices 660 (e.g., a display or monitor, a keyboard, a mouse, a camera, a fingerprint reader, a video processor, etc.). It is understood that the above are merely a few illustrative examples to which the disclosed subject matter is not limited.

The information processing system 600 according to the disclosed subject matter may further include one or more system buses 605. In such an embodiment, the system bus 605 may be configured to communicatively couple the processor 610, the memories 620 and 630, the network interface 640, the user interface unit 650, and one or more hardware components 660. Data processed by the CPU 610 or data inputted from outside of the non-volatile memory 630 may be stored in either the non-volatile memory 630 or the volatile memory 640.

In various embodiments, the information processing system 600 may include or execute one or more software components 670. In some embodiments, the software components 670 may include an operating system (OS) and/or an application. In some embodiments, the OS may be configured to provide one or more services to an application and manage or act as an intermediary between the application and the various hardware components (e.g., the processor 610, a network interface 640, etc.) of the information processing system 600. In such an embodiment, the information processing system 600 may include one or more native applications, which may be installed locally (e.g., within the non-volatile memory 630, etc.) and configured to be executed directly by the processor 610 and directly interact with the OS. In such an embodiment, the native applications may include pre-compiled machine executable code. In some embodiments, the native applications may include a script interpreter (e.g., C shell (csh), AppleScript, AutoHotkey, etc.) or a virtual execution machine (VM) (e.g., the Java Virtual Machine, the Microsoft Common Language Runtime, etc.) that are configured to translate source or object code into executable code which is then executed by the processor 610.

The semiconductor devices described above may be encapsulated using various packaging techniques. For example, semiconductor devices constructed according to principles of the present inventive concepts may be encapsulated using any one of a package on package (POP) technique, a ball grid arrays (BGAs) technique, a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic metric quad flat package (PMQFP) technique, a plastic quad flat package (PQFP) technique, a small outline package (SOIC) technique, a shrink small outline package (SSOP) technique, a thin small outline package (TSOP) technique, a thin quad flat package (TQFP) technique, a system in package (SIP) technique, a multi-chip package (MCP) technique, a wafer-level fabricated package (WFP) technique, a wafer-level processed stack package (WSP) technique, or other technique as will be known to those skilled in the art.

Method steps may be performed by one or more programmable processors executing a computer program to perform functions by operating on input data and generating output. Method steps also may be performed by, and an apparatus may be implemented as, special purpose logic circuitry, e.g., an FPGA (field programmable gate array) or an ASIC (application-specific integrated circuit).

In various embodiments, a computer readable medium may include instructions that, when executed, cause a device to perform at least a portion of the method steps. In some embodiments, the computer readable medium may be included in a magnetic medium, optical medium, other medium, or a combination thereof (e.g., CD-ROM, hard drive, a read-only memory, a flash drive, etc.). In such an embodiment, the computer readable medium may be a tangibly and non-transitorily embodied article of manufacture.

While the principles of the disclosed subject matter have been described with reference to example embodiments, it will be apparent to those skilled in the art that various changes and modifications may be made thereto without departing from the spirit and scope of these disclosed concepts. Therefore, it should be understood that the above embodiments are not limiting, but are illustrative only. Thus, the scope of the disclosed concepts are to be determined by the broadest permissible interpretation of the following claims and their equivalents, and should not be restricted or limited by the foregoing description. It is, therefore, to be understood that the appended claims are intended to cover all such modifications and changes as fall within the scope of the embodiments.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the embodiments.

What is claimed is:

1. An apparatus comprising:
an expansion memory device, wherein the expansion memory device includes a plurality of memory chips;
a connection printed circuit board configured to be physically coupled with a memory socket; and
a connection cable configured to electrically couple the connection printed circuit board with the expansion memory device and transmit electrical signals therebetween.

2. The apparatus of claim 1, wherein the connection printed circuit board includes a buffer chip configured to receive data from a memory management device and transmit the data, via the connection cable, to the expansion memory device.

3. The apparatus of claim 1, wherein the expansion memory device includes at least one buffer chip configured to receive data via the connection cable and transmit the data to at least one of the memory chips.

4. The apparatus of claim 1, wherein the expansion memory device includes:
a plurality of printed circuit boards, each printed circuit board including a plurality of memory chips, and
a buffer circuit configured to:
receive, via the connection cable, data that is associated with a memory address,
determine, based at least in part upon the memory address, a destination memory chip of the plurality of memory chips that the data is associated with, and
transmit the data to the destination memory chip.

5. The apparatus of claim 1, wherein the connection printed circuit board is configured to communicate with a memory management device via a first protocol, and
wherein the connection printed circuit board is configured to communicate with the expansion memory device via a second protocol.

6. The apparatus of claim 1, wherein the expansion memory device is configured to be fixedly attached within a hard drive bay.

7. The apparatus of claim 1, wherein the connection printed circuit board includes at least one memory chip.

8. The apparatus of claim 1, wherein the connection printed circuit board and the connection cable are included by an integrated connection cable.

9. The apparatus of claim 8, wherein the integrated connection cable comprises flexible plastic.

10. The apparatus of claim 1, wherein the memory socket is configured to be coupled with an in-line memory module.

11. A system comprising:
a processor configured to execute instructions and access data stored within a memory chip;
a memory socket configured to electrically couple the processor with a memory chip;
an expansion memory device, wherein the expansion memory device includes a plurality of memory chips;
a connection printed circuit board configured to be physically coupled with a memory socket; and
a connection cable configured to electrically couple the printed circuit board with the expansion memory device and transmit electrical signals therebetween.

12. The system of claim 11, further including an enclosure configured to house either a hard drive or the expansion memory device.

13. The system of claim 12, wherein the enclosure includes a plurality of bays, and wherein each bay is configured to house either a hard drive or the expansion memory device;
wherein the expansion memory device is fixedly attached within a first bay; and
wherein a hard drive is fixedly attached within a second bay.

14. The system of claim 11, further including:
a plurality of memory sockets, each configured to electrically couple the processor with respective memory chips, and
at least one in-line memory module that includes a plurality of memory chips; and
wherein the in-line memory module is coupled with a first memory socket of the plurality of the memory sockets,
wherein the connection printed circuit board is coupled with a second memory socket of the plurality of the memory sockets, and
wherein the processor is configured to communicate with each memory chip via a standard protocol regardless of whether the memory chip is included by the in-line memory module or the expansion memory device.

15. The system of claim 11, wherein the expansion memory device includes:
a plurality of memory cards, each memory card including a plurality of memory chips.

16. The system of claim 11, further including a memory management unit configured to regulate and manage memory accesses by the processor to the memory chips.

17. A method comprising:
fixedly attaching an expansion memory device within a component bay of a computing system, wherein the expansion memory device includes a plurality of memory chips, each memory chip configured to store data;
coupling the expansion memory device with a connection cable, wherein the connection cable is configured to transport signals between the expansion memory device and a memory connector plug; and
coupling the memory connector plug with a memory socket, wherein the memory socket is configured to receive a memory access request from a memory management unit.

18. The method of claim 17, further including coupling a memory module with a second memory socket, wherein the memory module includes a second plurality of memory chips; and
wherein the memory management unit is configured to access, via a first protocol, either a memory chip of the expansion memory device or a memory chip of the memory module.

19. The method of claim 17, wherein the expansion memory device includes a plurality of modular memory cards, each memory card including a plurality of memory chips.

20. The method of claim 17, wherein fixedly attaching an expansion memory device includes removing a hard drive from the component bay.
